(19) United States
(12) Patent Application Publication
(10) Pub. No.: US 2025/0357289 A1
(43) Pub. Date: Nov. 20, 2025

(54) SEMICONDUCTOR DEVICE AND METHOD OF FORMING THE SAME

(71) Applicant: Taiwan Semiconductor Manufacturing Company, Ltd., Hsinchu (TW)

(72) Inventors: Chien-Chang Lin, New Taipei City (TW); Chih-Kai Cheng, Hsinchu County (TW); Yen-Fu Su, Hsinchu (TW); Chien-Chia Chiu, Taoyuan City (TW)

(73) Assignee: Taiwan Semiconductor Manufacturing Company, Ltd., Hsinchu (TW)

(21) Appl. No.: 18/664,301

(22) Filed: May 15, 2024

(51) Int. Cl. H01L 23/498; H01L 23/00; H01L 23/31

(52) U.S. Cl. CPC H01L 23/49816; H01L 23/3128; H01L 24/05; H01L 24/13; H01L 24/97; H01L 2224/05009; H01L 2224/05025; H01L 2224/13009; H01L 2224/13025; H01L 2224/97; H01L 2924/01029; H01L 2924/01079; H01L 2924/1431; H01L 2924/1434; H01L 2924/15311; H01L 2924/182

(57) ABSTRACT

A semiconductor device includes a substrate, a passivation layer, a conductive pad, a conductive connector and an adhesion promotion pattern. The passivation layer is disposed on the substrate. The conductive pad is disposed in the passivation layer. The conductive connector is disposed on and electrically connected to the conductive pad. The adhesion promotion pattern is protruded from a surface of the passivation layer, wherein the adhesion promotion pattern is electrically isolated from the conductive connector.

### BACKGROUND

In recent years, the semiconductor industry has experienced rapid growth due to continuous improvement in integration density of various electronic components, e.g., transistors, diodes, resistors, capacitors, etc. For the most part, this improvement in integration density has come from successive reductions in minimum feature size, which allows more components to be integrated into a given area.

These smaller electronic components also require smaller packages that occupy less area than previous packages. Examples of the type of packages for semiconductors include quad flat pack (QFP), pin grid array (PGA), ball grid array (BGA), flip chips (FC), three-dimensional integrated circuits (3DICs), wafer level packages (WLPs), and package on package (POP) devices. Some 3DICs are prepared by placing chips over chips on a semiconductor wafer level. The 3DICs provide improved integration density and other advantages, such as faster speeds and higher bandwidth, because of the decreased length of interconnects between the stacked chips. However, there are many challenges related to 3DICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 1D are schematic cross-sectional views of various stages in a method of forming a semiconductor device according to some embodiments.

FIG. 2A to FIG. 2F are respectively a schematic top view of a semiconductor device in accordance with some embodiments.

FIG. 3A to FIG. 3E are schematic cross-sectional views of various stages in a method of forming a semiconductor device according to some embodiments.

FIG. 4 is a schematic top view of a semiconductor device according to some embodiments.

FIG. 5A to FIG. 5D are schematic cross-sectional views of various stages in a method of forming a semiconductor device according to some embodiments.

FIG. 6 is a schematic cross-sectional view of a semiconductor device according to some embodiments.

FIG. 7A to FIG. 7C are schematic cross-sectional views of various stages in a method of forming a semiconductor device according to some embodiments.

FIG. 8 is a schematic cross-sectional view of a semiconductor device according to some embodiments.

FIG. 9 is a schematic cross-sectional view of a semiconductor device according to some embodiments.

FIG. 10A is a schematic cross-sectional view of a semiconductor device according to some embodiments, and FIG. 10B is a schematic top view of a semiconductor device in accordance with some embodiments.

FIG. 11 is a schematic cross-sectional view of a semiconductor device according to some embodiments.

FIG. 12 illustrates a flowchart of a method of forming a semiconductor device according to some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

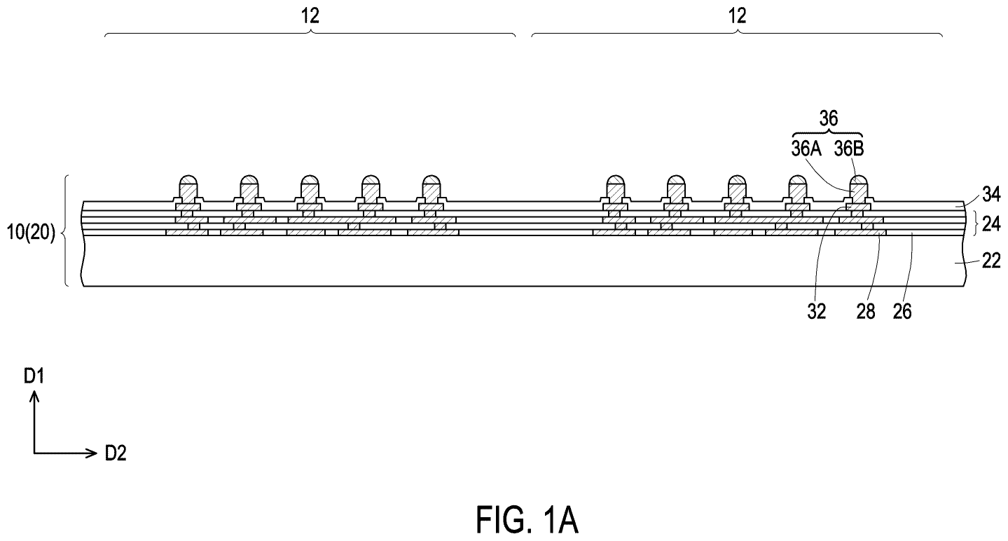

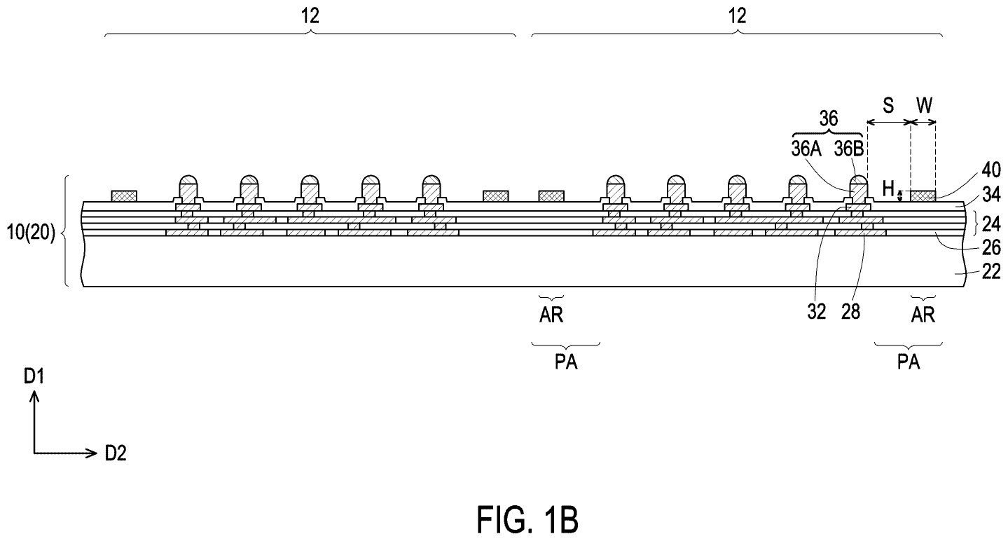

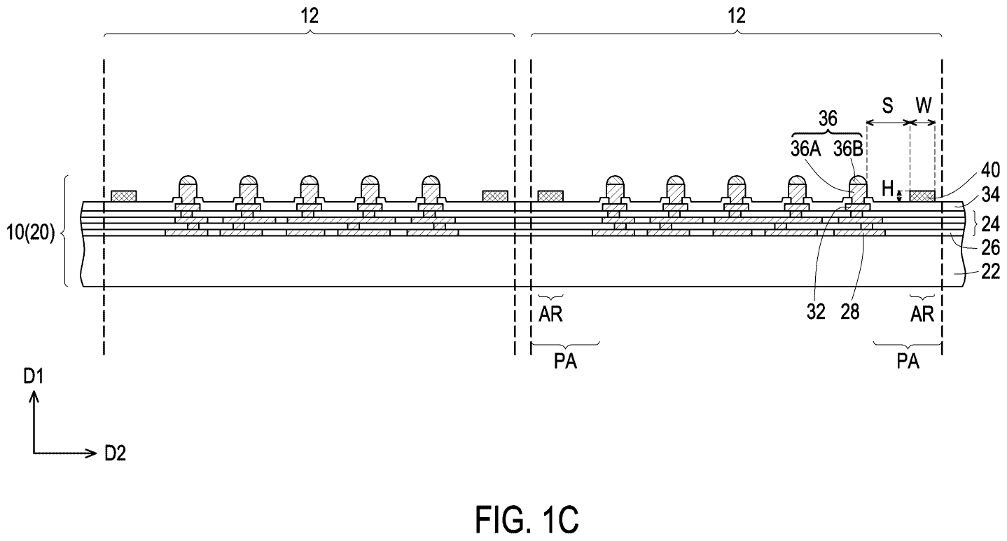

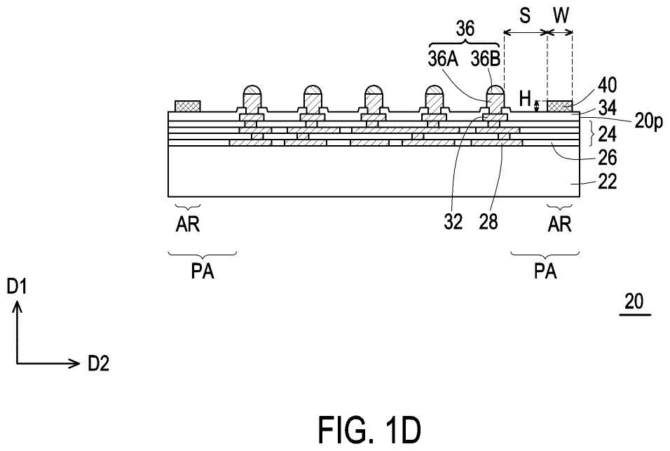

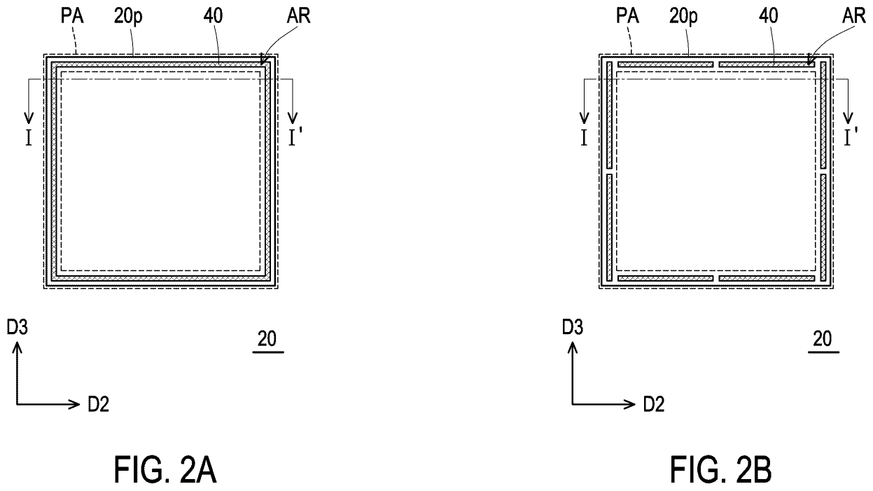

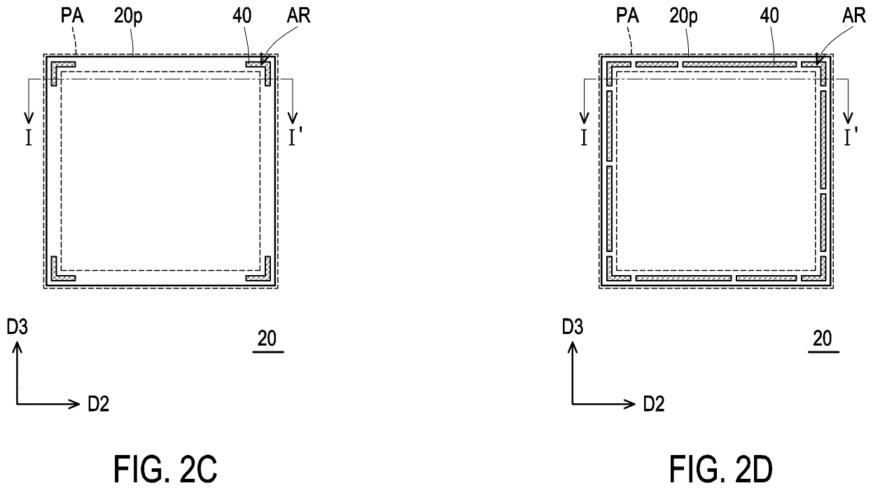

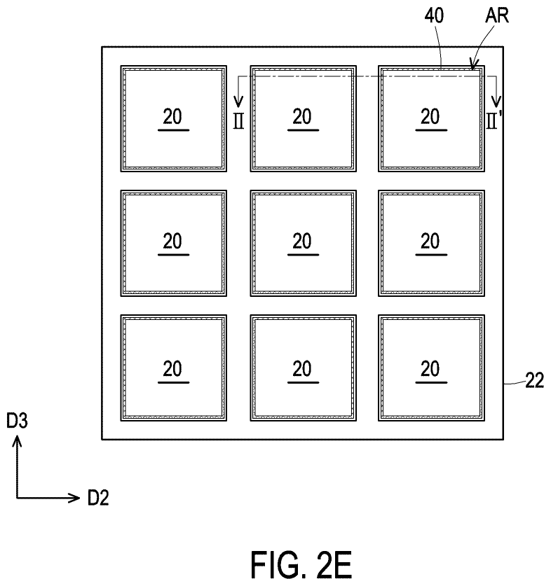

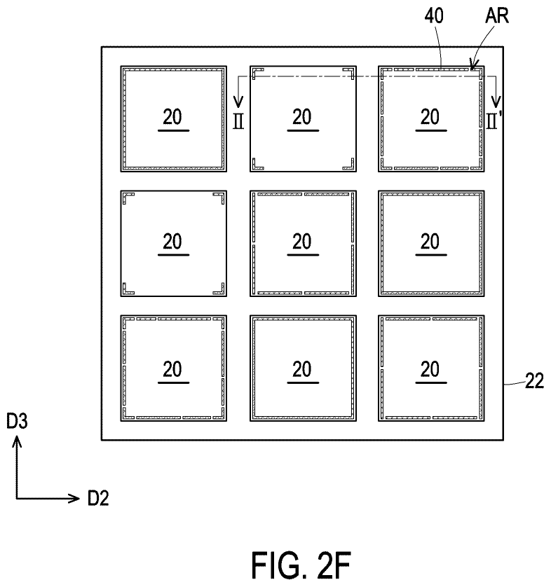

FIG. 1A to FIG. 1D are schematic cross-sectional views of various stages in a method of forming a semiconductor device according to some embodiments. FIG. 2A to FIG. 2F are respectively a schematic top view of a semiconductor device in accordance with some embodiments. For simplicity and clarity of illustration, only few elements are shown in the top view of FIG. 2A to FIG. 2D. In some embodiments, FIG. 1D is a cross-sectional view of a semiconductor device along the line I-I′ of FIG. 2A to FIG. 2D, and FIG. 1A to FIG. 1C is a cross-sectional view of a semiconductor device along the line II-II′ of FIG. 2A to FIG. 2D.

Referring to FIG. 1A, a wafer 10 is provided. The wafer 10 has a first surface (e.g., a front-side) and a second surface (e.g., a backside) opposite to the first surface. The wafer 10 may include a plurality of die regions 12 that are singulated in subsequent steps to form a plurality of integrated circuits 20. For example, the die regions 12 are separated by scribe line regions (not shown) therebetween. In some embodiments, the integrated circuits 20 have the same size (e.g., same height and/or surface area). In alternative embodiments, the integrated circuits 20 have different sizes (e.g., different heights and/or surface areas). The integrated circuits 20 may be of the same type or different types. Each integrated circuit 20 may be a logic die (e.g., central processing unit (CPU), graphics processing unit (GPU), system-on-integrated-chips (SoIC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), the like, or combinations thereof. The integrated circuit 20 will be packaged in subsequent processing to form a semiconductor device such as a semiconductor package.

The integrated circuit 20 may include a substrate 22 and an interconnect structure 24 along a first direction D1 (e.g., z direction). The substrate 22 may be a semiconductor substrate such as a substrate of silicon, doped or undoped, or an active layer of a semiconductor-on-insulator (SOI) substrate. The substrate 22 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The substrate 22 has a front-side (e.g., active) surface and a backside (e.g., non-active) surface opposite to the front-side surface.

Devices (not shown) may be formed at the front-side (e.g., active) surface of the substrate 22. The devices may be active devices (e.g., transistors, diodes, etc.), capacitors, resistors, the like, or combinations thereof. An inter-layer dielectric (ILD) (not separately illustrated) is over the front-side (e.g., active) surface of the substrate 22. The ILD surrounds and may cover the devices. The ILD may include one or more dielectric layers formed of materials such as phospho-silicate glass (PSG), boro-silicate glass (BSG), boron-doped phospho-silicate glass (BPSG), undoped silicate glass (USG), or the like.

Conductive plugs (not separately illustrated) may extend through the ILD to electrically and physically couple the devices. For example, when the devices are transistors, the conductive plugs couple the gates and source and drain regions of the transistors. The conductive plugs may be formed of tungsten, cobalt, nickel, copper, silver, gold, aluminum, the like, or combinations thereof.

The interconnect structure 24 is over the active or the front-side (e.g., active) surface of the substrate 22, and is used to electrically connect the devices of the substrate 22 to form an integrated circuit. The interconnect structure 24 may be over the ILD and the conductive plugs. The interconnect structure 24 may include one or more dielectric layer(s) and respective electrical routing(s) in the dielectric layer(s). For example, the interconnect structure 24 includes a plurality of dielectric layers 26 and a plurality of electrical routings 28. Acceptable dielectric materials for the dielectric layers 26 include low-k dielectric materials such as PSG, BSG, BPSG, USG, or the like. Acceptable dielectric materials for the dielectric layers 26 further include oxides such as silicon oxide or aluminum oxide; nitrides such as silicon nitride; carbides such as silicon carbide; the like; or combinations thereof such as silicon oxynitride, silicon oxycarbide, silicon carbonitride, silicon oxycarbonitride or the like. Other dielectric materials may also be used, such as a polymer such as polybenzoxazole (PBO), polyimide, a benzocyclobuten (BCB) based polymer, or the like. The electrical routings 28 may include conductive vias and/or conductive lines to interconnect the devices of the substrate 22. The electrical routings 28 may be formed of a conductive material, such as a metal, such as copper, cobalt, aluminum, gold, combinations thereof, or the like. Each electrical routing 28 may be formed in and/or on the dielectric layer 26. The interconnect structure 24 may be formed by a damascene process, such as a single damascene process, a dual damascene process, or the like.

In some embodiments, the integrated circuit 20 further includes conductive pads 32, to which external connections are made. The conductive pads 32 may be aluminum pads. The conductive pads 32 may be formed on the interconnect structure 24 and electrically connected to the electrical routings 28. In some embodiments, one or more passivation layers 34 are formed on portions of the interconnect structure 24 and the conductive pads 32. The passivation layer 34 may be also referred to as dielectric layer.

In some embodiments, a plurality of conductive connectors 36 are formed on and electrically connected to the interconnect structure 24 to provide an external electrical connection to the circuitry and devices. For example, an opening is formed to extend through the passivation layer 34 to the conductive pad 32, and a conductive connector 36 is formed in the opening in the passivation layer 34 to contact the conductive pad 32. As shown in FIG. 1A, the conductive connectors 36 are arranged along a second direction (e.g., x direction) D2 and a third direction (e.g., y direction) D3 (shown in FIGS. 2A to 2D) substantially perpendicular to the first direction D1. In some embodiments, the conductive connectors 36 are ball grid array (BGA) connectors, solder balls, metal pillars, controlled collapse chip connection (C4) bumps, micro bumps, electroless nickel-electroless palladium-immersion gold technique (ENEPIG) formed bumps, or the like.

The conductive connectors 36 may include underbump metallizations (UBMs) 36A and solder regions 36B over the UBMs 36A. The UBMs 36A may be conductive pillars, pads, or the like. In some embodiments, the UBMs 36A may be formed by forming a seed layer over the interconnect structure 24. The seed layer may be a metal layer, which may be a single layer or a composite layer including a plurality of sub-layers formed of different materials. In some embodiments, the seed layer includes a titanium layer and a copper layer over the titanium layer. The seed layer may be formed using, for example, PVD or the like. A photoresist is then formed and patterned on the seed layer. The photoresist may be formed by spin coating or the like and may be exposed to light for patterning. The pattern of the photoresist corresponds to the UBMs 36A. The patterning forms openings through the photoresist to expose the seed layer. A conductive material is then formed in the openings of the photoresist and on the exposed portions of the seed layer. The conductive material may be formed by plating, such as electroplating or electroless plating, or the like. The conductive material may include a metal, such as copper, titanium, tungsten, aluminum, nickel, or the like. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process. The remaining portions of the seed layer and conductive material form the UBMs 36A.

In some embodiments, the UBMs 36A includes three layers of conductive materials, such as a layer of titanium, a layer of copper, and a layer of nickel. Other arrangements of materials and layers, such as an arrangement of chrome/chrome-copper alloy/copper/gold, an arrangement of titanium/titanium tungsten/copper, or an arrangement of copper/nickel/gold, may be utilized for the formation of the UBMs 36A. Any suitable materials or layers of material that may be used for the UBMs 36A are fully intended to be included within the scope of the current application.

The solder regions 36B may include a solder material and may be formed over the UBMs 36A by dipping, printing, plating, or the like. The solder material may include, for example, lead-based and lead-free solders, such as Pb—Sn compositions for lead-based solder; lead-free solders including InSb; tin, silver, and copper (SAC) compositions; and other eutectic materials that have a common melting point and form conductive solder connections in electrical applications. For lead-free solder, SAC solders of varying compositions may be used, such as SAC 105 (Sn 98.5%, Ag 1.0%, Cu 0.5%), SAC 285, and SAC 405, as examples. Lead-free solders may further include SnCu compounds as well, without the use of silver (Ag). Lead-free solders may also include tin and silver, Sn—Ag, without the use of copper. A reflow process may be performed, giving the solder regions 36B a shape of a partial sphere. In alternative embodiments, the solder regions 36B have other shapes, such as non-spherical shapes.

In some embodiments, the solder regions 36B are used to perform chip probe (CP) testing on the integrated circuit 20. For example, the solder regions are solder balls, solder bumps, or the like, which are used to attach a chip probe to the conductive connectors 36. Chip probe testing may be performed on the integrated circuit 20 to ascertain whether the integrated circuit 20 is a known good die (KGD). Thus, only integrated circuits 20, which are KGDs, undergo subsequent processing and are packaged, and dies which fail the chip probe testing are not packaged. In some embodiments, after testing, the solder regions 36B are removed in subsequent processing steps. In some embodiments, a thinning process (not shown) is performed onto the backside surface before forming the conductive connectors 36, so as to reduce the thickness of the wafer 10. In some embodiments, the thinning process is performed for total thickness variation (TTV) control. The thinning process may be a grinding process, a CMP, an etch-back, combinations thereof, or the like. In alternative embodiments, the grinding process is omitted.

Referring to FIG. 1B, an adhesion promotion pattern 40 is disposed in an area AR on the integrated circuit 20. The area AR is, for example, a portion of the periphery area PA of the integrated circuit 20. In some embodiments, the area AR is a corner area. In some embodiments, the adhesion promotion pattern 40 is formed on the passivation layer (e.g., outermost passivation layer) 34 in one or more areas AR of the integrated circuit 20. For example, as shown in FIGS. 2A, 2B and 2D, the adhesion promotion pattern 40 is disposed in the area AR (e.g., an entirety of the periphery area PA) of the integrated circuit 20. As shown in FIG. 2C, the adhesion promotion pattern 40 is disposed in four areas AR (e.g., four corner areas of the periphery area PA) of the integrated circuit 20. However, the disclosure is not limited thereto. In alternative embodiments, the adhesion promotion pattern 40 is disposed in portion(s) of the periphery area PA such as in one, two or three of the corner areas. The adhesion promotion pattern 40 is electrically isolated from the conductive connector 36, and adhesion promotion pattern 40 is physically separated from the outermost conductive connector 36 by a spacing S, for example. The spacing S may be in a range of 0 to several millimeters (e.g., 1 to 3 mm) based on the requirements. In an embodiment in which the spacing S is 0, the adhesion promotion pattern 40 is in direct contact with the conductive connector 36. A material of the adhesion promotion pattern 40 may have polar/reactive functional group(s) such as C═O, —COOH, —OH and —NH at the outermost surface thereof. For example, the material of the adhesion promotion pattern 40 has more dipole-dipole moments/interactions than the outermost layer (such as the passivation layer 34) of the integrated circuit 20. In some embodiments, the material of the adhesion promotion pattern 40 is a polymer with adhesive property such as polyimide, polybenzoxazole (PBO), benzocyclobutene (BCB) or a combination thereof. The adhesion promotion pattern 40 includes polymer such as polyimide while the passivation layer 34 contacting the adhesion promotion pattern 40 includes silicon nitride, for example. The adhesion promotion pattern 40 may be formed by a deposition process, a coating process, a lamination process, a printing process, a dispensing process, the like, combinations thereof, or any other suitable process. In some embodiments, a patterning process such as a lithography process is further performed, to pattern the material of the adhesion promotion pattern 40. In alternative embodiments, the adhesion promotion pattern 40 is pre-formed and then placed onto or adhered to the integrated circuit 20. The adhesion promotion pattern may be also referred to as adhesion promotion layer.

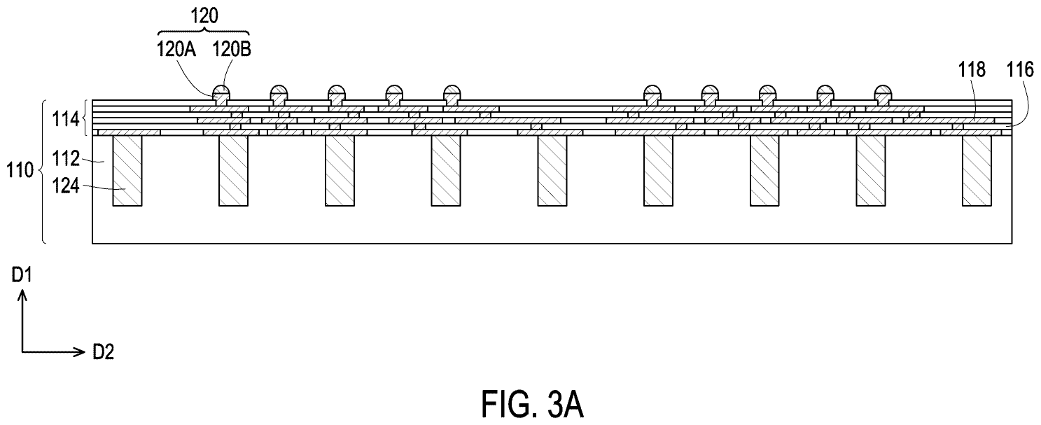

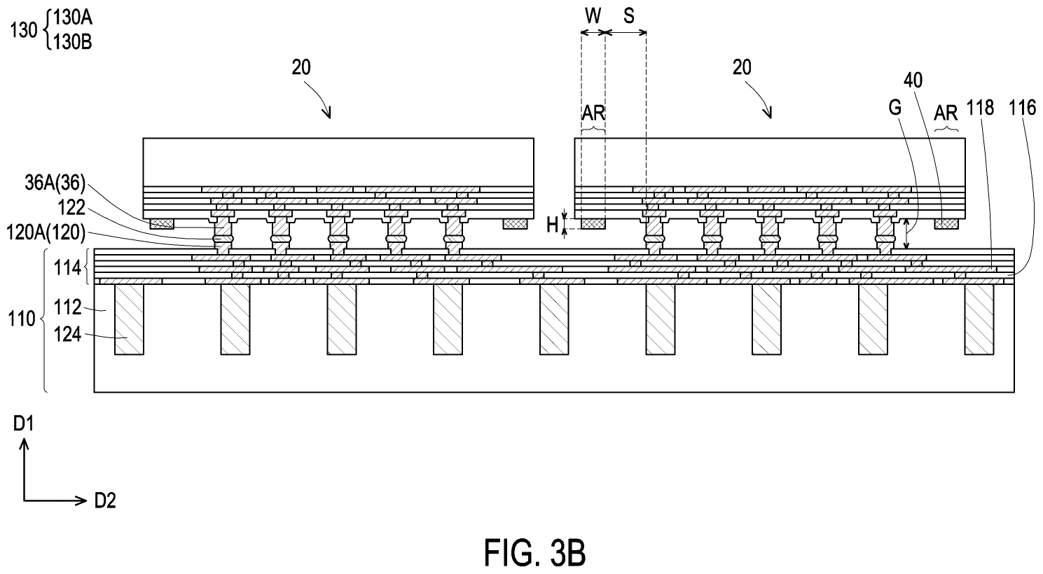

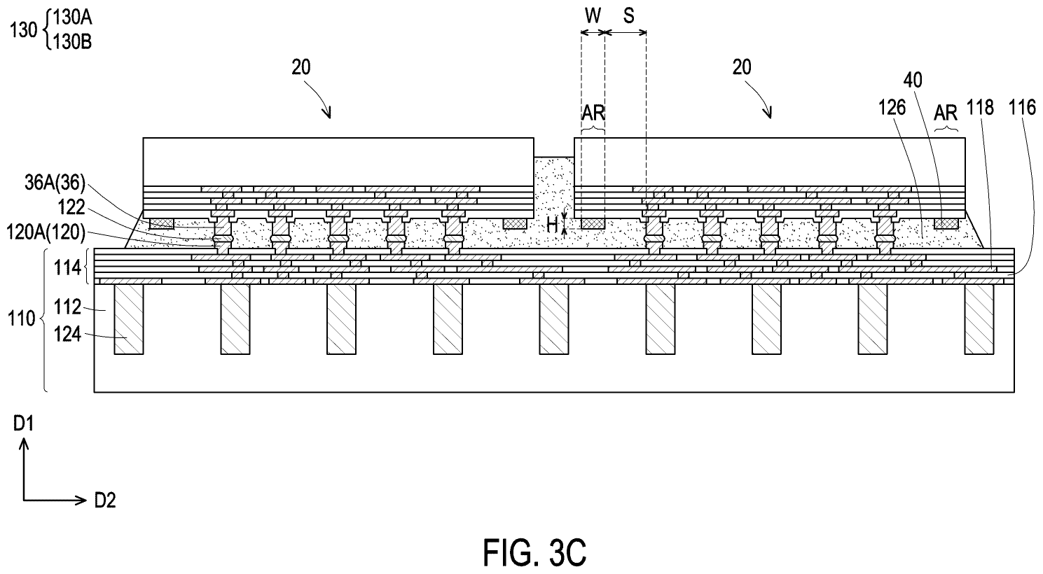

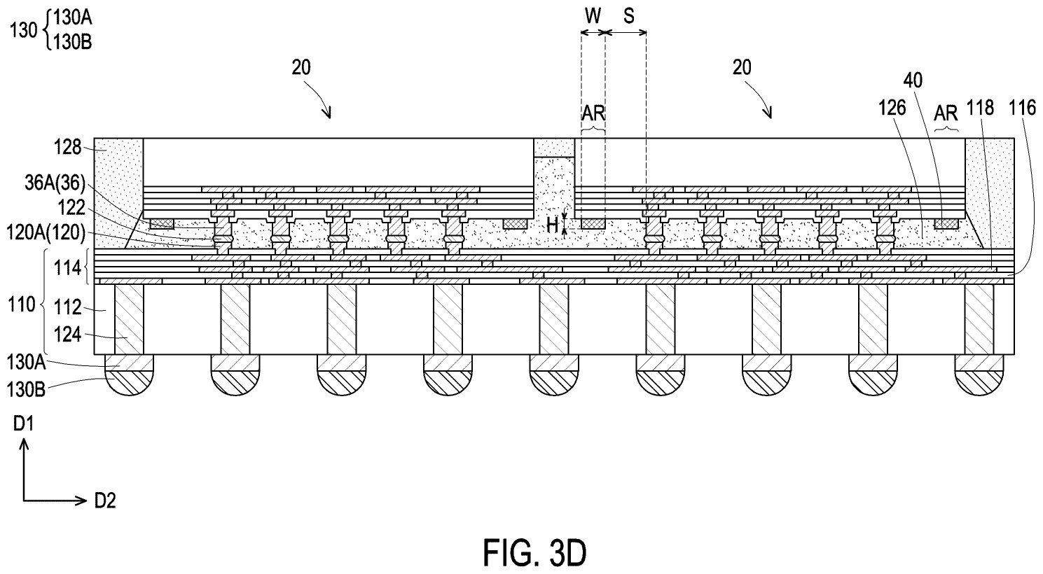

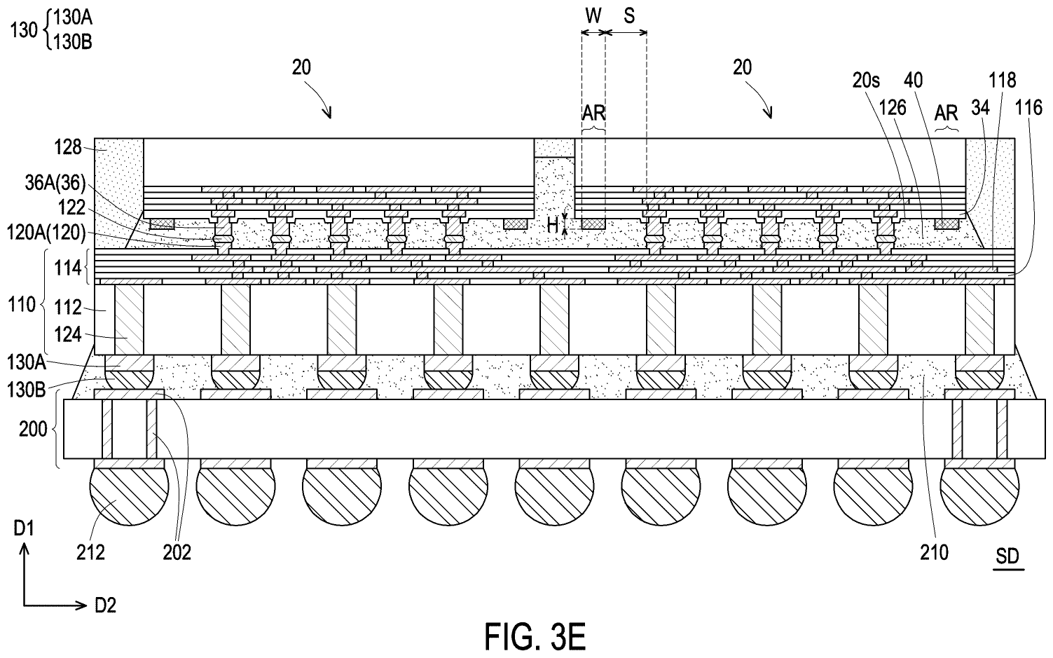

In some embodiments, the adhesion promotion pattern 40 has a height H and a width W. The height His smaller than or substantially equal to a height of the conductive connector 36 and a gap G (shown in FIG. 3B) to be formed between the integrated circuit 20 and the interposer 110, for example. The height H of the adhesion promotion pattern 40 may be measured from a first surface (e.g., bottom surface) of the adhesion promotion pattern 40 on the passivation layer 34 to a second surface (e.g., top surface) of the adhesion promotion pattern 40. The height H of the adhesion promotion pattern 40 is in a range of 3 μm to 10 μm along the first direction D1 (e.g., z direction), for example. In an embodiment, the height H is in a range of 5 μm to 8 μm. The width W of the adhesion promotion pattern 40 may be measured from an outer sidewall of the adhesion promotion pattern 40 to an inner sidewall of the adhesion promotion pattern 40 facing the conductive connector 36. The width W of the adhesion promotion pattern 40 is larger than 0.2 mm along the second direction (e.g., x direction) D2 and/or the third direction (e.g., y direction) D3, for example. In an embodiment, the width W is in a range of 3 mm to 7 mm. From a top view, the adhesion promotion pattern 40 is ring-shaped (e.g., FIG. 2A), bar-shaped/rectangular (e.g., FIG. 2B and FIG. 2D), L-shaped (e.g., FIG. 2C and FIG. 2D), the like or of any suitable shape.

The adhesion promotion pattern 40 may continuously or non-continuously extend along a periphery of the integrated circuit 20. In some embodiments, as shown in FIG. 2A, the adhesion promotion pattern 40 continuously extends along the periphery 20p and continuously surrounds the conductive connectors 36 of the integrated circuit 20. In such embodiments, the adhesion promotion pattern 40 is a closed and continuous pattern and the integrated circuit 20 may include a single adhesion promotion pattern 40. In alternative embodiments, as shown in FIGS. 2B to 2D, the adhesion promotion patterns 40 are arranged along the periphery 20p to surround the conductive connectors 36 of the integrated circuit 20. In such embodiments, the adhesion promotion patterns 40 are individual elements and separated from each other. The adhesion promotion patterns 40 may have identical or similar shape (as shown in FIG. 2B and FIG. 2C) or different shapes (as shown in FIG. 2D). In some embodiments, the adhesion promotion patterns 40 of different integrated circuits 20 have the same shape (as shown in FIG. 2E), arrangement, material and/or the like. However, the disclosure is not limited thereto. In alternative embodiments, the adhesion promotion patterns 40 of different integrated circuits 20 have different shape (as shown in FIG. 2F), arrangement, material and/or the like.

Referring to FIG. 1C, a singulation process is performed on the wafer-level structure of FIG. 1B by cutting along scribe line regions (e.g., dashed lines), e.g., around the die region 12. It is noted that the periphery area PA of the integrated circuit 20 is inside the scribe line region. The singulation process may include sawing, etching, dicing, the like, or combinations thereof. For example, the singulation process includes sawing the substrate 22 and the interconnect structure 24. The singulation process singulates the die region 12 from adjacent regions to form a singulated integrated circuit 20 illustrated in FIG. 1D. In other words, the singulated integrated circuit 20 is obtained from the die region 12. Each integrated circuit 20 has the adhesion promotion pattern 40 on the outermost surface of the integrated circuit 20, and the adhesion promotion pattern 40 covers the area(s) AR (e.g., corner area(s)) of the integrated circuit 20. The adhesion promotion pattern 40 is disposed in the periphery area PA of the integrated circuit 20. An outer sidewall of the adhesion promotion pattern 40 is substantially flush with the periphery 20p of the integrated circuit 20, for example. In some embodiments, the adhesion promotion pattern 40 is formed before the singulation process. However, the disclosure is not limited thereto. The adhesion promotion pattern 40 may be formed after the singulation process or before the formation of the conductive connector 36. For example, the adhesion promotion pattern 40 is disposed on the integrated circuit 20 after dicing and before integrating onto an interposer.

FIG. 3A to FIG. 3E are schematic cross-sectional views of various stages in a method of forming a semiconductor device according to some embodiments.

Referring to FIG. 3A, an interposer 110 is obtained or formed. In some embodiments, the interposer 110 includes a substrate 112, an interconnect structure 114, and conductive connectors 120. In alternative embodiments, an interposer wafer including a plurality of package regions is obtained or formed. The interposer wafer includes an interposer in the package region, which will be singulated in subsequent processing to be included in a semiconductor device such as a semiconductor package.

The substrate 112 may be formed using similar materials and methods as the substrate 22 described above with reference to FIG. 1A, and the description is not repeated herein. In some embodiments, the substrate 112 generally does not include active devices therein, although the interposers 110 may include passive devices formed in and/or on an active or a front-side surface (e.g., the surface facing upward in FIG. 3A) of the substrate 112. In alternative embodiments, active devices (e.g., transistors, diodes, etc.), capacitors, resistors, the like, or combinations thereof, are formed in and/or on the front-side surface of the substrate 112.

The interconnect structure 114 is formed over the front-side surface of the substrate 112, and is used to electrically connect the devices (if any) of the substrate 112. The interconnect structure 114 may include one or more dielectric layer(s) and respective electrical routing(s) in the dielectric layer(s). For example, the interconnect structure 114 includes a plurality of dielectric layers 116 and a plurality of electrical routings 118. Acceptable dielectric materials for the dielectric layers 116 include oxides such as silicon oxide or aluminum oxide; nitrides such as silicon nitride; carbides such as silicon carbide; the like; or combinations thereof such as silicon oxynitride, silicon oxycarbide, silicon carbonitride, silicon oxycarbonitride or the like. Acceptable dielectric materials for the dielectric layers 116 further include low-k dielectric materials such as PSG, BSG, BPSG, USG, or the like. Other dielectric materials may also be used, such as a polymer such as polybenzoxazole (PBO), polyimide, a benzocyclobuten (BCB) based polymer, or the like. The electrical routings 118 may include conductive vias and/or conductive lines to interconnect the devices of the substrate 112. The electrical routings 118 may be formed of a conductive material, such as a metal, such as copper, cobalt, aluminum, gold, combinations thereof, or the like. Each electrical routing 118 may be formed in and/or on the dielectric layer 116. The interconnect structure 114 may be formed by a damascene process, such as a single damascene process, a dual damascene process, or the like. The conductive connectors 120 are similar to the conductive connectors 36, for example. In some embodiments, the conductive connectors 120 include underbump metallizations (UBMs) 120A and solder regions 120B over the UBMs 120A.

Conductive vias 124 may extend into the interconnect structure 114 and/or the substrate 112. The conductive vias 124 are electrically connected to the electrical routings 118 of the interconnect structure 114. The conductive vias 124 are also sometimes referred to as through substrate vias (TSVs). As an example to form the conductive vias 124, recesses can be formed in the interconnect structure 114 and/or the substrate 112 by, for example, etching, milling, laser techniques, the like, or combinations thereof. A thin dielectric material may be formed in the recesses, such as by using an oxidation technique. A thin barrier layer may be conformally deposited in the openings, such as by CVD, atomic layer deposition (ALD), physical vapor deposition (PVD), thermal oxidation, the like, or combinations thereof. The barrier layer may be formed of an oxide, a nitride, a carbide, combinations thereof, or the like. A conductive material may be deposited over the barrier layer and in the openings. The conductive material may be formed by an electro-chemical plating process, CVD, ALD, PVD, the like, or combinations thereof. Examples of conductive materials are copper, tungsten, aluminum, silver, gold, the like, or combinations thereof. Excess conductive material and barrier layer is removed from a surface of the interconnect structure 114 or the substrate 112 by, for example, a CMP. Remaining portions of the barrier layer and conductive material form the conductive vias 124.

Referring to FIG. 3B, integrated circuits 20 are bonded to the interposer 110, and a gap G is formed between the integrated circuits 20 and the interposer 110. The gap G may be in a range of 7 μm to 25 μm. A difference between the gap G and the height H of the adhesion promotion pattern 40 is larger than 0.5G, for example. If the difference between the gap G and the height H of the adhesion promotion pattern 40 is smaller than 0.5 G, the filling of the underfill 126 may be difficult. In some embodiments, the integrated circuits 20 are picked and placed onto the interposer 110. In alternative embodiments in which the interposer wafer is provided, the integrated circuits 20 are picked and placed onto each package region of the interposer wafer. In some embodiments, each integrated circuit 20 has a structure of FIG. 1D. In other words, the integrated circuit 20 has the adhesion promotion pattern 40 thereon. However, the disclosure is not limited thereto. In alternative embodiments, an integrated circuit without the adhesion promotion pattern may be also integrated onto the interposer 110. The integrated circuits 20 may have the same or different function.

In some embodiments, the integrated circuits 20 are attached to the interconnect structure 114 of the interposer 110 using the conductive connectors 36 and 120. The integrated circuits 20 may be placed on the interconnect structure 114 using, e.g., a pick-and-place tool. After placing the integrated circuits 20 on the interconnect structure 114, the solder regions 36B of the conductive connectors 36 are in physical contact with respective solder regions 120B of respective conductive connectors 120. After placing the integrated circuits 20 on the interconnect structure 114, a reflow process may be performed on the conductive connectors 36 and 120. The reflow process may melt and merges the solder regions 36B and 120B into solder joints 122. The solder joints 122 electrically and mechanically couple the integrated circuits 20 to the interconnect structure 114, for example.

In some embodiments, in the first direction D1 (e.g., z direction), after bonding the integrated circuit 20 and the interposer 110, the adhesion promotion pattern 40 is disposed at a gap G formed between the integrated circuit 20 and the interposer 110. In the second direction (e.g., x direction) D2, the adhesion promotion pattern 40 may be disposed adjacent to the bonded structure of the conductive connectors 36 and in a region (e.g., die to die region) between the integrated circuits 20, for example.

Referring to FIG. 3C, an underfill 126 may be formed around the solder joints 122, and in the gap G between the interposer 110 and the integrated circuits 20. The underfill 126 may reduce stress and protect the solder joints 122. The underfill 126 may be formed of an underfill material such as a molding compound, epoxy, or the like. The underfill 126 may be formed by a capillary flow process after the integrated circuits 20 are attached to the interconnect structure 114, or may be formed by a suitable deposition method before the integrated circuits 20 are attached to the interconnect structure 114. The underfill 126 may be applied in liquid or semi-liquid form and then subsequently cured. In some embodiments, the underfill 126 partially or fully fills gaps (e.g., die to die region) between adjacent ones of the integrated circuits 20, such that the underfill 126 extends along sidewalls of the integrated circuits 20.

In some embodiments, the adhesion promotion pattern 40 is disposed between the underfill 126 and one of the integrated circuit 20 and the interposer 110. As shown in FIG. 3C, in some embodiments in which the adhesion promotion pattern 40 is formed on the integrated circuit 20, the adhesion promotion pattern 40 is disposed between the underfill 126 and the integrated circuit 20. The adhesion promotion pattern 40 physically contacts the integrated circuit 20 and a portion of the underfill 126 in the area AR, that is, the portion of the underfill 126 adheres to the integrated circuit 20 through the adhesion promotion pattern 40, for example. In some embodiments, the area AR corresponds to the periphery area PA (e.g., corner area(s) or edge area(s)) of the integrated circuit 20 and is also referred to as a high delamination risk area. In other words, during performing the subsequent process such as reflow process, delamination (peeling off) between the integrated circuit 20 and the underfill 126 may occur in the area AR (e.g., corner area(s) or edge area(s)) due to the package corner stress, the bowing of the integrated circuit or the like, and thus the warpage may occur. In such embodiments, a gap is formed between the integrated circuit 20 and the underfill 126. In some embodiments, the adhesion promotion pattern 40 covers the area AR and physically contacts the underfill 126. Since the adhesion promotion pattern 40 has more dipole-dipole moments/interactions than the outermost layer (such as the passivation layer 34) of the integrated circuit 20, the adhesion between the adhesion promotion pattern 40 and the underfill 126 is improved. Accordingly, the adhesion promotion pattern 40 physically connects the portion of the underfill 126 in the area AR to the integrated circuit 20, and the adhesion between the underfill 126 and the integrated circuit 20 may be improved. Thus, the delamination and/or peeling risk may be reduced or prevented.

Referring to FIG. 3D, an encapsulant 128 is formed on and around the integrated circuits 20. In some embodiments, the encapsulant 128 encapsulates the integrated circuits 20 and the underfill 126. The encapsulant 128 covers sidewalls of the integrated circuits 20 and fills the gaps between the integrated circuits 20. The encapsulant 128 may be a molding compound, epoxy, or the like. The encapsulant 128 may not include fillers therein. The encapsulant 128 may be applied by compression molding, transfer molding, or the like, and is formed over the interposer 110 such that the integrated circuits 20 are buried or covered. The encapsulant 128 may be applied in liquid or semi-liquid form and then subsequently cured. In some embodiments, the outer sidewalls of the interposer 110 and the encapsulant 128 are laterally coterminous (within process variations).

Then, the substrate 112 is thinned to expose the conductive vias 124. Exposure of the conductive vias 124 may be accomplished by a thinning process, such as a grinding process, a CMP, an etch-back, combinations thereof, or the like. In some embodiments (not separately illustrated), the thinning process for exposing the conductive vias 124 includes a CMP, and the conductive vias 124 protrude at a backside surface of the interposer 110 as a result of dishing that occurs during the CMP. In such embodiments, an insulating layer (not separately illustrated) is optionally be formed on the backside of the substrate 112, surrounding the protruding portions of the conductive vias 124. The insulating layer may be formed of a silicon-containing insulator, such as, silicon nitride, silicon oxide, silicon oxynitride, or the like, and may be formed by a suitable deposition method such as spin coating, CVD, plasma-enhanced CVD (PECVD), high density plasma CVD (HDP-CVD), or the like. After the substrate 112 is thinned, the exposed surfaces of the conductive vias 124 and the insulating layer (if present) or the substrate 112 are coplanar (within process variations), such that they are level with one another, and are exposed at the backside of the interposer 110.

Subsequently, conductive connectors 130 are formed on the backside surface of the interposer 110 as the conductive connectors 36 described above with reference to FIG. 1C, and the description is not repeated herein. In the illustrated embodiment, the conductive connectors 130 includes UBMs 130A, and solder regions 130B over the UBMs 130A. The UBMs 130A and the solder regions 130B may be formed using similar material and methods as the UBMs 36A and the solder regions 36B, respectively, described above with reference to FIG. 1C, and the description is not repeated herein. During the formation of the conductive connectors 130, the thermal process such as reflow process may be performed. As mentioned above, since the adhesion promotion pattern 40 physically connects the portion of the underfill 126 in the area AR to the integrated circuit 20, and the adhesion between the underfill 126 and the integrated circuit 20 may be improved. Thus, the delamination and/or peeling risk after the thermal process may be reduced or prevented.

In alternative embodiments in which the interposer wafer is provided, a singulation process is performed after forming the conductive connectors 130. The singulation process is performed on the package component by cutting along scribe line regions, e.g., around the package region. The singulation process may include sawing, etching, dicing, the like, or combinations thereof. In such embodiments, the singulation process includes sawing the encapsulant 128, the interconnect structure 114 and the substrate 112. The singulation process singulates the package region from adjacent package regions to form a singulated semiconductor device as illustrated in FIG. 3D. The singulated semiconductor device is from the package region. The singulation process forms interposers 110 from the singulated portions of the interposer wafer.

Referring to FIG. 3E, a board substrate 200 is formed below and electrically connected to the interposer 110. In some embodiments, the interposer 110 is bonded to the board substrate 200 through the conductive connectors 130. During the bonding process, the thermal process such as reflow process may be performed. As mentioned above, since the adhesion promotion pattern 40 physically connects the portion of the underfill 126 in the area AR to the integrated circuit 20, and the adhesion between the underfill 126 and the integrated circuit 20 may be improved. Thus, the delamination and/or peeling risk after the thermal process may be reduced or prevented.

As shown in FIG. 3E, the adhesion promotion pattern 40 is protruded from a surface 20s (e.g., outermost surface) of the integrated circuit 20 (e.g., an outermost surface of the passivation layer 34). In some embodiments, a first surface (e.g., the bottom surface) of the adhesion promotion pattern 40 is higher than a first surface (e.g., the bottom surface) of the conductive connectors 36 while a second surface (e.g., the top surface) opposite to the first surface of the adhesion promotion pattern 40 is lower a second surface (e.g., the top surface) opposite to the first surface of the conductive connectors 36. However, the disclosure is not limited thereto. In alternative embodiments, the first surface (e.g., the bottom surface) of the adhesion promotion pattern 40 is lower or substantially flush with the first surface (e.g., the bottom surface) of the conductive connectors 36, but higher than a surface (e.g., top surface) of the interposer 110. The first surface (e.g., the bottom surface) of the adhesion promotion pattern 40 is higher than the first surface (e.g., the bottom surface) of a portion of the passivation layer 34 vertically interposed between the conductive connector 36 and the conductive pads 32, for example. A thickness of a first portion of the underfill 126 vertically overlapping with the adhesion promotion pattern 40 is smaller than a thickness of a second portion of the underfill 126 vertically sandwiched between the interposer 110 and the integrated circuit 20, and the thickness of the second portion of the underfill 126 is smaller than a thickness of a third portion of the underfill 126 horizontally sandwiched between the integrated circuits 20.

In some embodiments, the board substrate 200 includes a core layer and two build-up layers on opposite sides of the core layer. In some embodiments, the core layer includes prepreg (which contains epoxy, resin, and/or glass fiber), polyimide, photo image dielectric (PID), the like, or a combination thereof. In some embodiments, the build-up layers include prepreg (which contains epoxy, resin, and/or glass fiber), polyimide, polybenzoxazole (PBO), benzocyclobutene (BCB), a nitride such as silicon nitride, an oxide such as silicon oxide, phosphosilicate glass (PSG), borosilicate glass (BSG), boron-doped phosphosilicate glass (BPSG), the like, or a combination thereof. The material of the core layer may be different from the material of the build-up layers. In some embodiments, the board substrate 200 includes wiring patterns 202 that penetrate through the core layer and the build-up layers for providing electrical routings between different interposers, dies or die stacks. The wiring patterns 202 include lines, vias, pads and/or connectors. The board substrate 200 is referred to as a “printed circuit board (PCB)” in some examples. In other embodiments, the core layer of the board substrate 200 may be omitted as needed, and such board substrate 200 is referred to as a “coreless board substrate”.

Thereafter, an underfill 210 is formed to fill the space between the interposer 110 and the board substrate 200, and surrounds the conductive connectors 130. In some embodiments, the underfill 210 includes a molding compound such as epoxy, and is formed using dispensing, injecting, and/or spraying process.

Afterwards, conductive connectors 212 are formed below and electrically connected to the board substrate 200. In some embodiments, each conductive connector 212 is electrically to the wiring patterns 202 of the board substrate 200. In some embodiments, the conductive connectors 212 include solder bumps, and/or may include metal pillars (e.g., copper pillars), solder caps formed on metal pillars, and/or the like. The conductive connectors 212 are referred to as “ball grid array (BGA) balls” in some examples. The conductive connectors 212 may be formed by a suitable process such as evaporation, electroplating, ball drop, or screen printing. During the formation of the conductive connectors 212, the thermal process such as reflow process may be performed. As mentioned above, since the adhesion promotion pattern 40 physically connects the portion of the underfill 126 in the area AR to the integrated circuit 20, and the adhesion between the underfill 126 and the integrated circuit 20 may be improved. Thus, the delamination and/or peeling risk after the thermal process may be reduced or prevented. In some embodiments, a semiconductor device SD of the disclosure is thus completed. The semiconductor device SD may be chip on wafer on substrate (CoWoS) structure. However, the disclosure is not limited thereto.

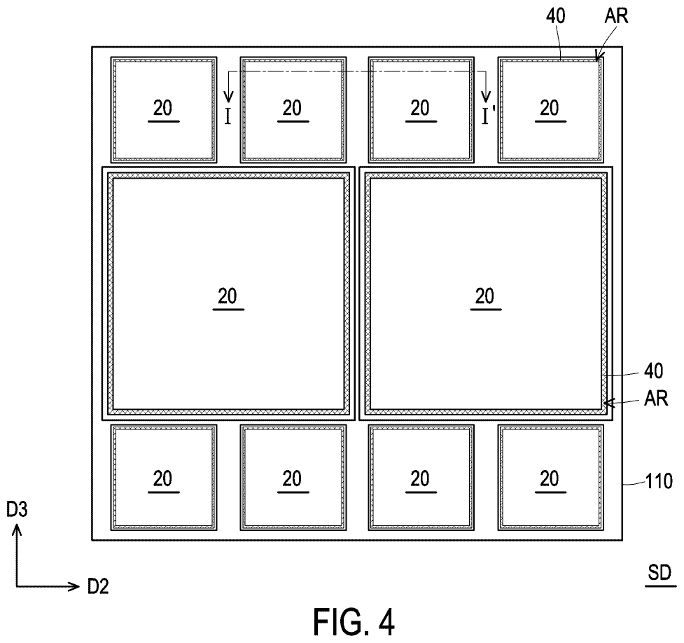

FIG. 4 is a schematic top view of a semiconductor device according to some embodiments. For simplicity and clarity of illustration, only few elements are shown in the top view of FIG. 4. In some embodiments, FIG. 3E is a cross-sectional view along the line I-I′ of FIG. 4.

Referring to FIG. 3E and FIG. 4, the semiconductor device includes the integrated circuits 20 disposed over and electrically connected to the interposer 110. The integrated circuits 20 are arranged along the second and third directions D2 and D3. In some embodiments, the integrated circuit 20 has the adhesion promotion pattern 40 in the area AR where the delamination between the integrated circuit 20 and the underfill 126 may occur, and thus the delamination is reduced or prevented. It is noted that the adhesion promotion patterns 40 of different integrated circuits 20 are illustrated as having the same shape, however, the disclosure is not limited thereto. In alternative embodiments, the adhesion promotion patterns 40 of the integrated circuits 20 have different shape, arrangement, material and/or the like. Furthermore, the size, the number and/or the arrangement of the integrated circuits may be adjusted upon the requirements.

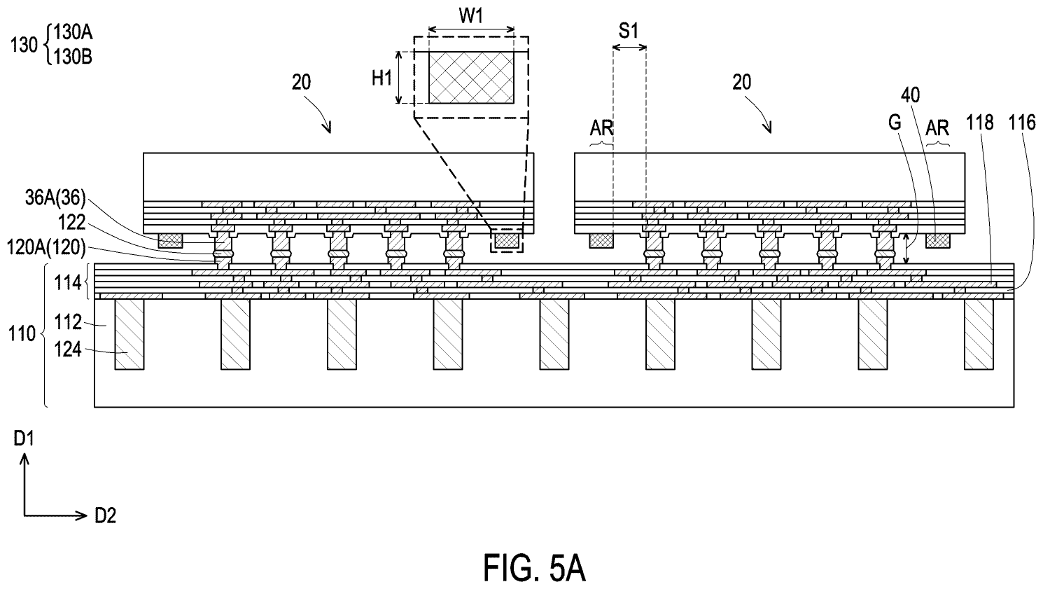

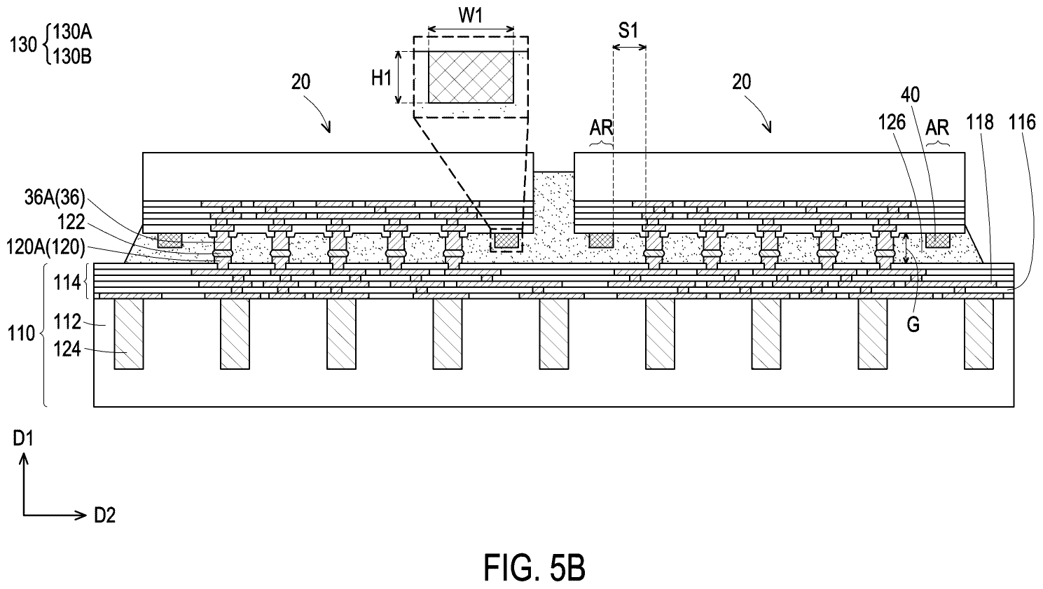

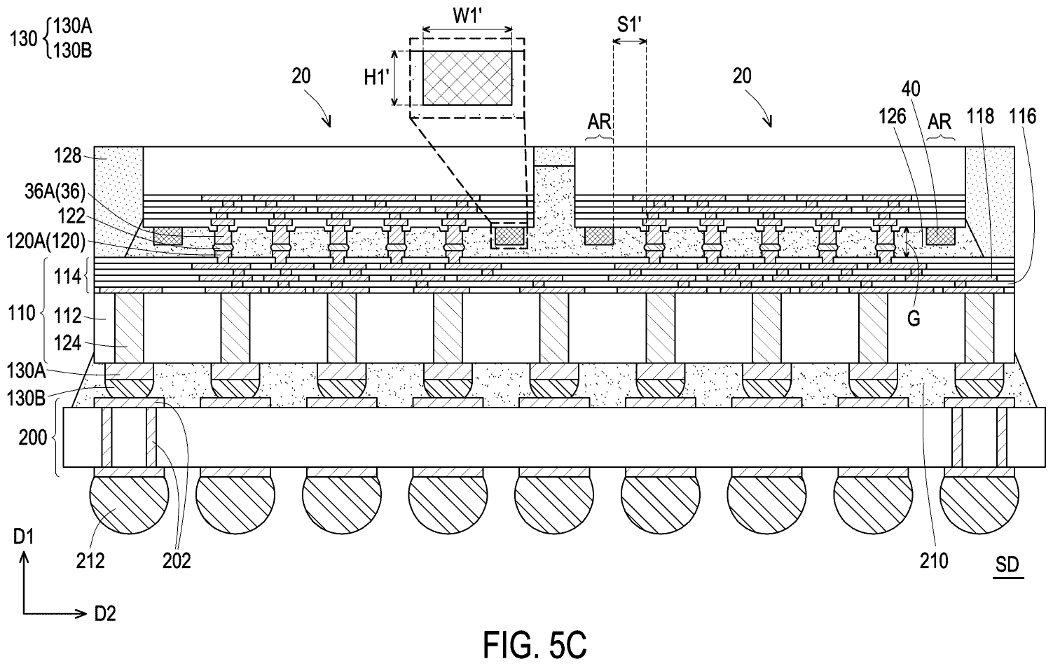

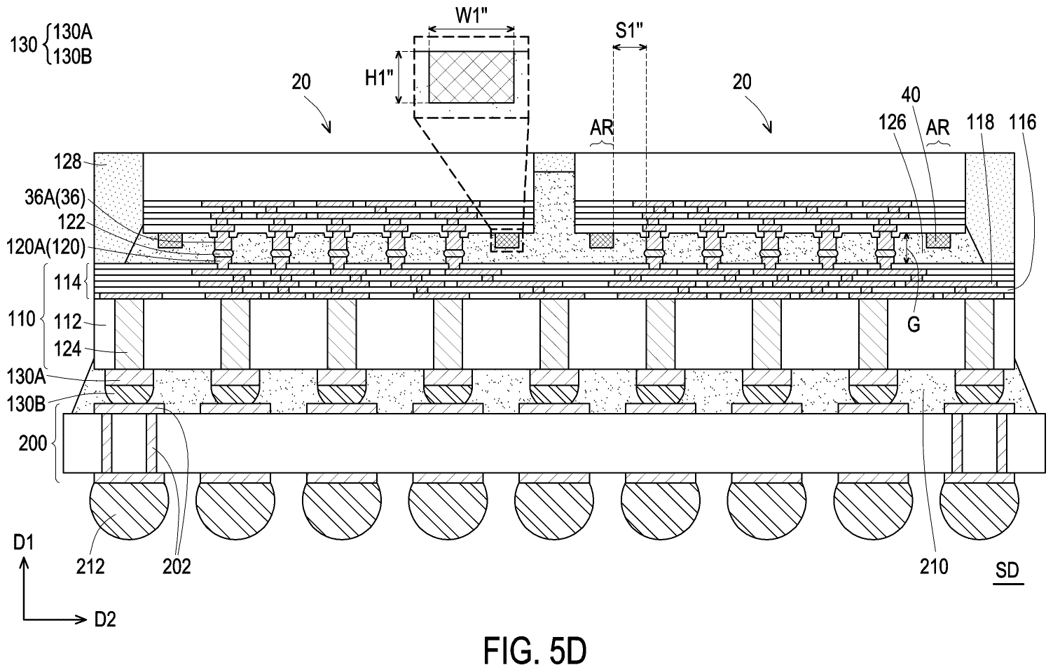

FIG. 5A to FIG. 5D are schematic cross-sectional views of various stages in a method of forming a semiconductor device according to some embodiments. The difference between the method of FIG. 5A to FIG. 5D and the method of FIG. 3A to FIG. 3E lies in that the adhesion promotion pattern is expanded during the thermal process.

Referring to FIG. 5A, integrated circuits 20 and an interposer 110 are bonded, and a gap G is formed between the integrated circuits 20 and the interposer 110. The integrated circuits 20, the interposer 110 and the bonding method may be similar to those described with reference to FIGS. 3A and 3B, so the detailed descriptions thereof are omitted herein. In some embodiments, a coefficient of thermal expansion (CTE) of the adhesion promotion pattern 40 is larger than a CTE of the passivation layer 34. In some embodiments, a material of the adhesion promotion pattern 40 has a CTE larger than about 25 ppm/K at room temperature (e.g., about 25° C.) and a CTE larger than about 90 ppm/K at a high temperature (e.g., higher than 200° C.). In other words, the adhesion promotion pattern 40 is expandable at a predetermined temperature. The predetermined temperature is the temperature used in the subsequent process (e.g., thermal process), for example. In some embodiments, a material of the adhesion promotion pattern 40 is a polymer with expandable property such as polyimide, polybenzoxazole (PBO) and benzocyclobutene (BCB). For example, the adhesion promotion pattern 40 includes polyimide while the passivation layer 34 contacting the adhesion promotion pattern 40 includes silicon nitride. In some embodiments, the adhesion promotion pattern 40 of the integrated circuit 20 has a height H1 along the first direction D1 and a width W1 along the second direction D2 and/or the third direction D3. The adhesion promotion pattern 40 is physically separated from the outermost conductive connector 36 by a spacing S1. The height H1, the width W1 and the spacing S1 may be predetermined by the CTE of the adhesion promotion pattern 40 and/or the gap G between the integrated circuits 20 and the interposer 110. For example, the first height H1 is smaller than or substantially equal to 0.5G. The spacing S1 is larger than an expanded amount of the adhesion promotion pattern 40 during the subsequent thermal process.

Referring to FIG. 5B, an underfill 126 is formed between the integrated circuits 20 and the interposer 110 to fill the gap G. The material and forming method of the underfill 126 may be similar to those described with reference to FIG. 3C, so the detailed descriptions thereof are omitted herein. In some embodiments in which the adhesion promotion pattern 40 is formed on the integrated circuit 20, the adhesion promotion pattern 40 is disposed in an area AR where a delamination of the underfill 126 and the integrated circuit 20 may occur.

Referring to FIG. 5C, an encapsulant 128 is formed. Then, conductive connectors 130 are formed. The material and forming method of the encapsulant 128 and the conductive connectors 130 may be similar to those described with reference to FIG. 3D, so the detailed descriptions thereof are omitted herein. After that, the interposer 110 is bonded to a board substrate 200 through the conductive connectors 130. The material and forming method of the conductive connectors 130 and the board substrate 200 and the bonding process may be similar to those described with reference to FIG. 3E, so the detailed descriptions thereof are omitted herein.

In some embodiments, during the process such as the formation of the conductive connectors 130, the bonding process of the interposer 110 and the board substrate 200 and the formation of the conductive connectors 212, a thermal process such as a reflow process is performed. The thermal process may be performed at a peak temperature in a range of about 230° C. to about 250° C. In some embodiments, as shown in FIG. 5C, the adhesion promotion pattern 40 is expanded to have a height H1′ along the first direction D1 and a width W1′ along the second direction D2 and/or the third direction D3. The height H1′ is smaller than or substantially equal to 0.75G, for example. The expanded amount of the adhesion promotion pattern 40 along the first direction D1 (e.g., vertical expanded amount) is equal to the difference (e.g., H1′−H1) between the height H1′ and the height H1. In some embodiments, the expanded amount (e.g., Z CTE) is larger than about 25 ppm/K at room temperature (e.g., about 25° C.) and a CTE larger than about 90 ppm/K at a high temperature (e.g., higher than 200° C.). The expanded amount of the adhesion promotion pattern 40 along the second direction D2 or third direction D3 (e.g., horizontal expanded amount) is equal to the difference (e.g., W1′−W1) between the width W1 and the width W1′ and the difference (e.g., S1−S1′) between the spacing S1 and the spacing S1. The horizontal expanded amount is smaller than the spacing S1 to avoid internal strain, for example. In some embodiments, the vertical expanded amount of the adhesion promotion pattern 40 is not smaller than a gap which may be formed between the underfill 126 and the integrated circuit 20 during the thermal process such as reflow process and cause the delamination. In other words, the adhesion promotion pattern 40 is expanded to fill the gap which may be formed due to the thermal process, and thus the delamination between the underfill and the integrated circuit is reduced or prevented.

Referring to FIG. 5D, after the thermal process is finished, the adhesion promotion pattern 40 may contract. In some embodiments, after the thermal process is finished and the ambient temperature is lowered (e.g., back to room temperature), the adhesion promotion pattern 40 contracts. For example, after the formation of the conductive connectors 130, the bonding process of the interposer 110 and the board substrate 200 and/or the formation of the conductive connectors 212 is finished, the adhesion promotion pattern 40 contracts to the dimension (e.g., height H1″ and width W1″) equal to or about the initial dimension of the adhesion promotion pattern 40. That is, the adhesion promotion pattern 40 in the formed semiconductor device SD has a height H1″ about the height H1 of FIG. 5A and a width W1″ about the width W1 of FIG. 5A.

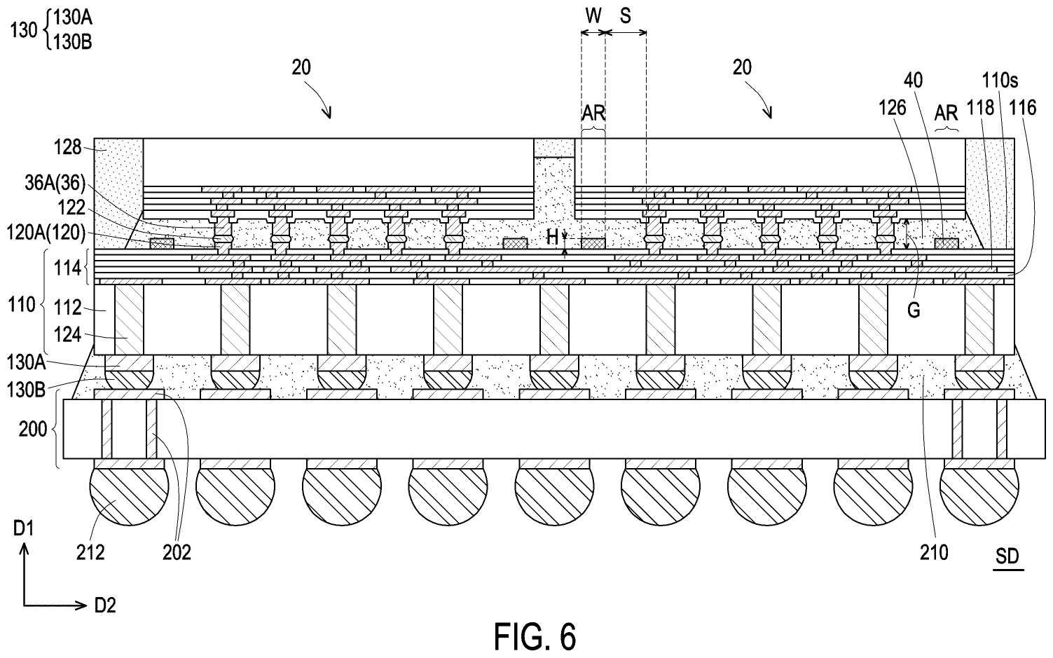

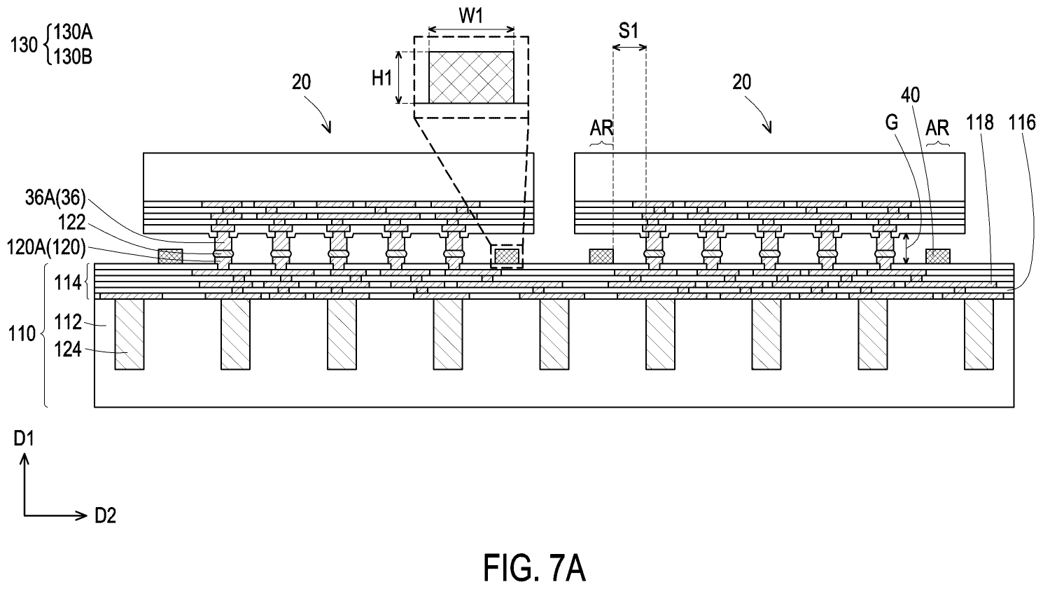

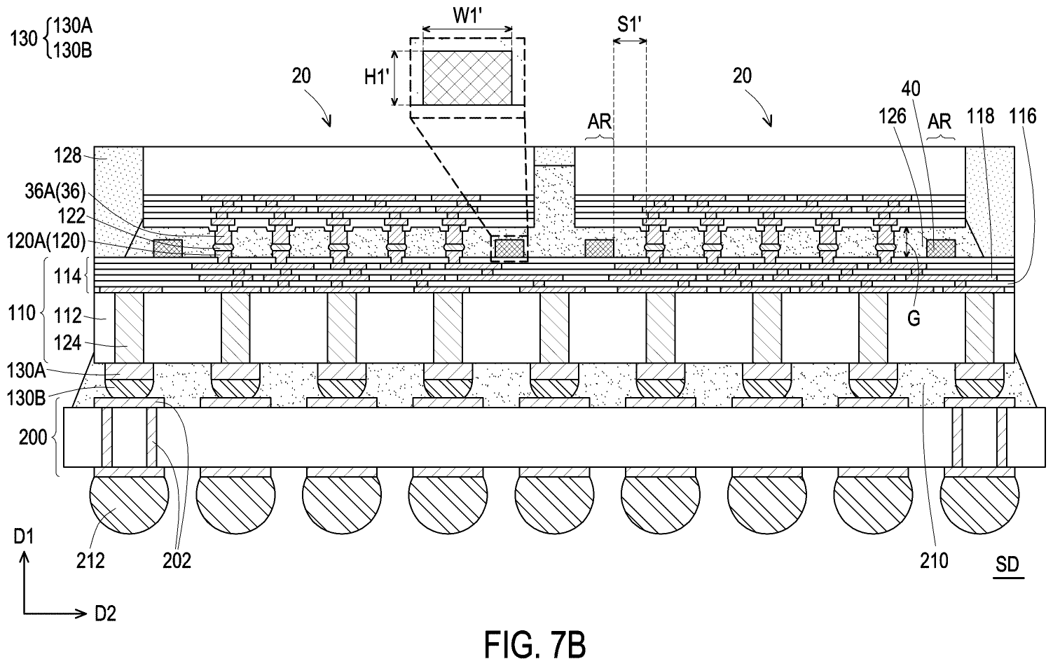

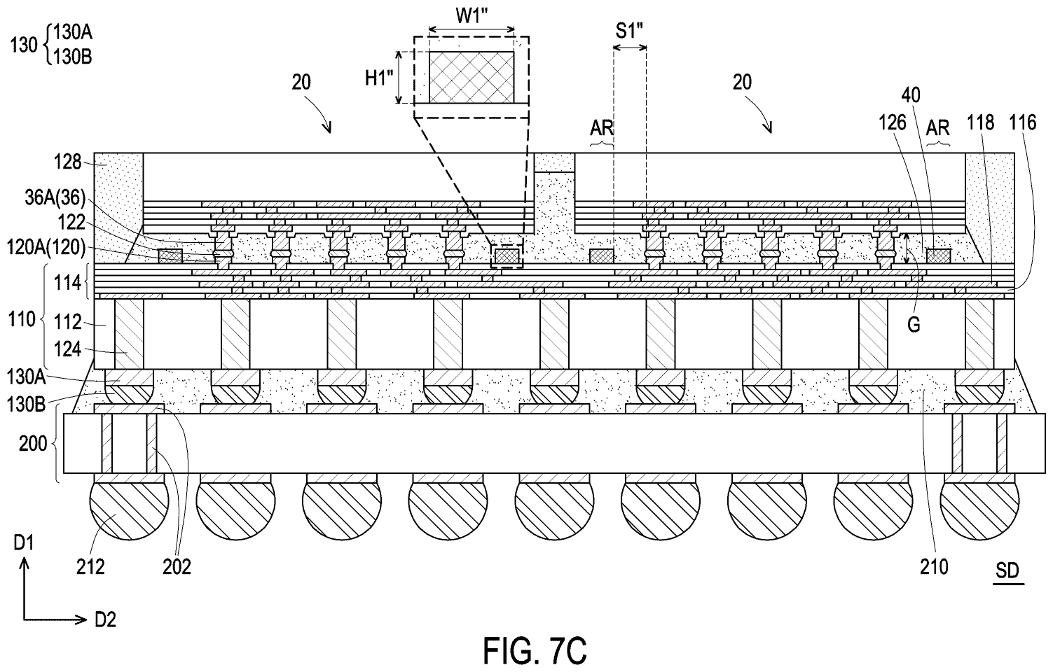

In the above embodiments, the adhesion promotion pattern 40 is formed on the integrated circuit 20. However, the disclosure is not limited thereto. In some embodiments, as shown in FIG. 6, the adhesion promotion pattern 40 may be formed on the interposer 110 corresponding to the area AR (e.g., periphery area PA) of the integrated circuit 20. As shown in FIG. 6, the adhesion promotion pattern 40 is protruded from a surface (e.g., outermost surface) 110s of the interposer 110 (e.g., a surface of the dielectric layer 116). The material, forming method and shape of the adhesion promotion pattern 40 may be similar to those described above, so the detailed descriptions thereof are omitted herein. In such embodiments, the adhesion promotion pattern 40 is formed on the outermost dielectric layer 106 of the interposer 110. The adhesion promotion pattern 40 is in direct contact with and physically connects a portion of the underfill 126 and the interposer 110, for example. The adhesion promotion pattern 40 on the interposer 110 may reduce or prevent the delamination between the underfill 126 and the integrated circuit 20 by adhering and/or anchoring the underfill 126 onto the integrated circuit 20. The adhesion promotion pattern 40 is ring-shaped (e.g., FIG. 2A), bar-shaped/rectangular (e.g., FIG. 2B and FIG. 2D), L-shaped (e.g., FIG. 2C and FIG. 2D), the like or of any suitable shape. In alternative embodiments, as shown in FIG. 7A to FIG. 7C, similar to those described with reference to FIG. 5A to FIG. 5D (e.g., FIG. 5A, FIG. 5C and FIG. 5D), during the formation of the semiconductor device SD, a height and a width of the adhesion promotion pattern 40 having may be expanded to H1′ and W1′ during the thermal process (e.g., reflow process) from H1 and W1, and then contract to W1″ and H1″ while the ambient temperature is lowered (e.g., back to room temperature).

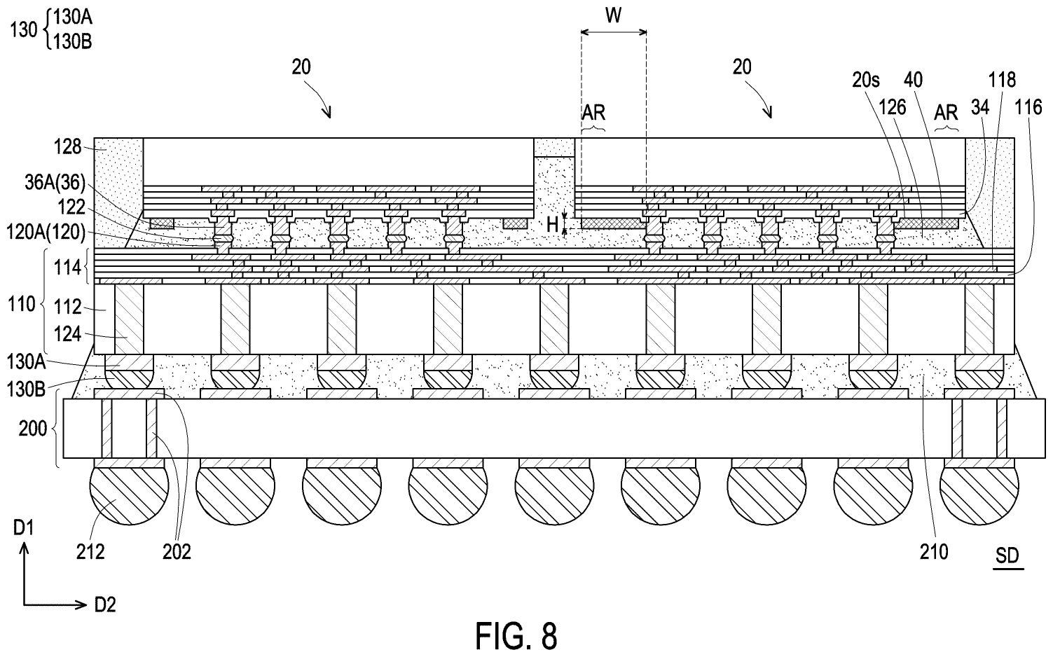

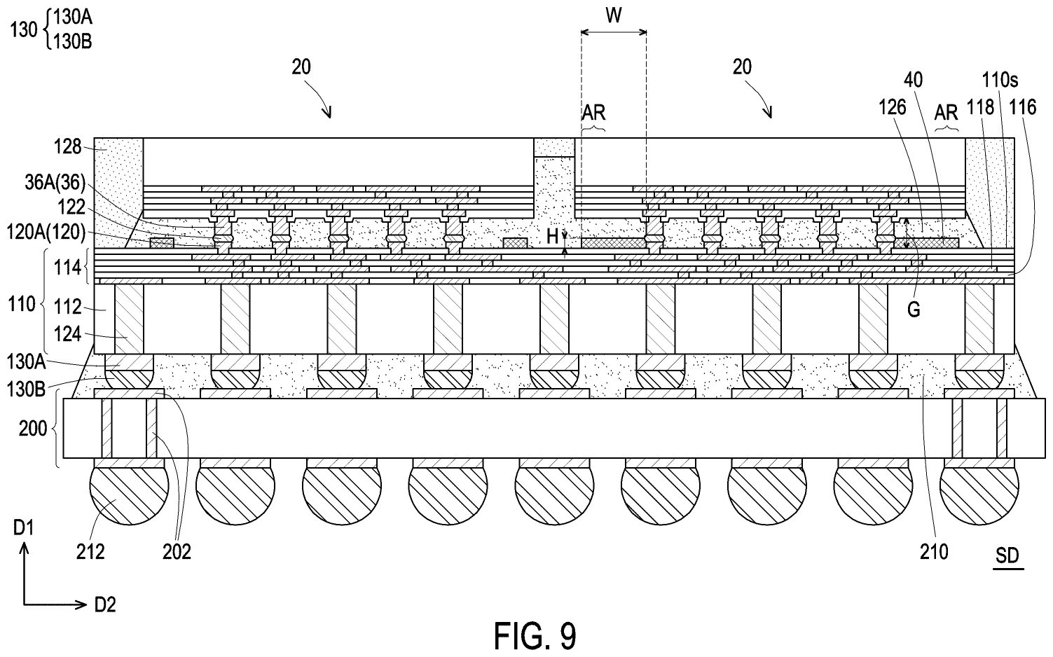

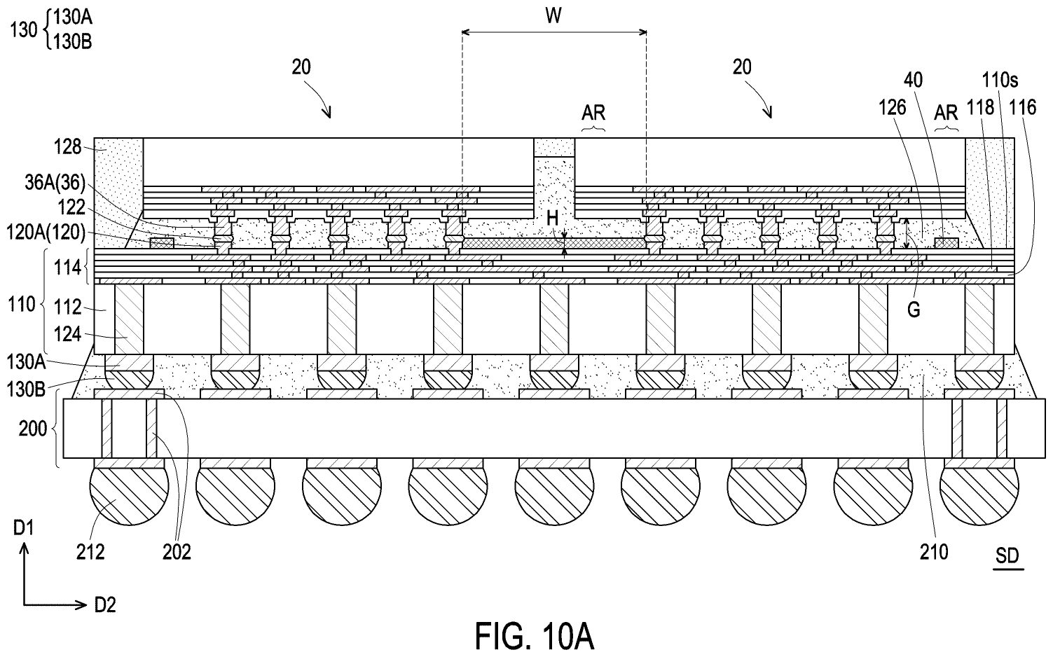

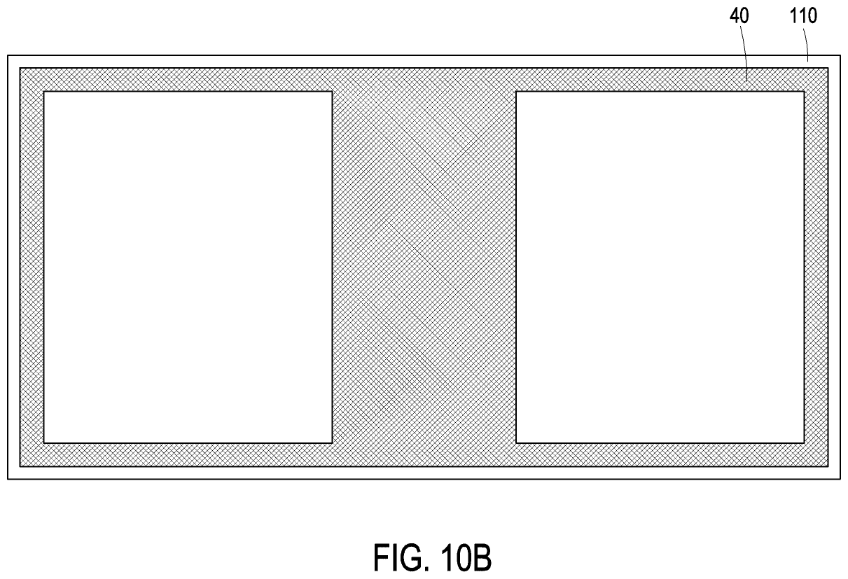

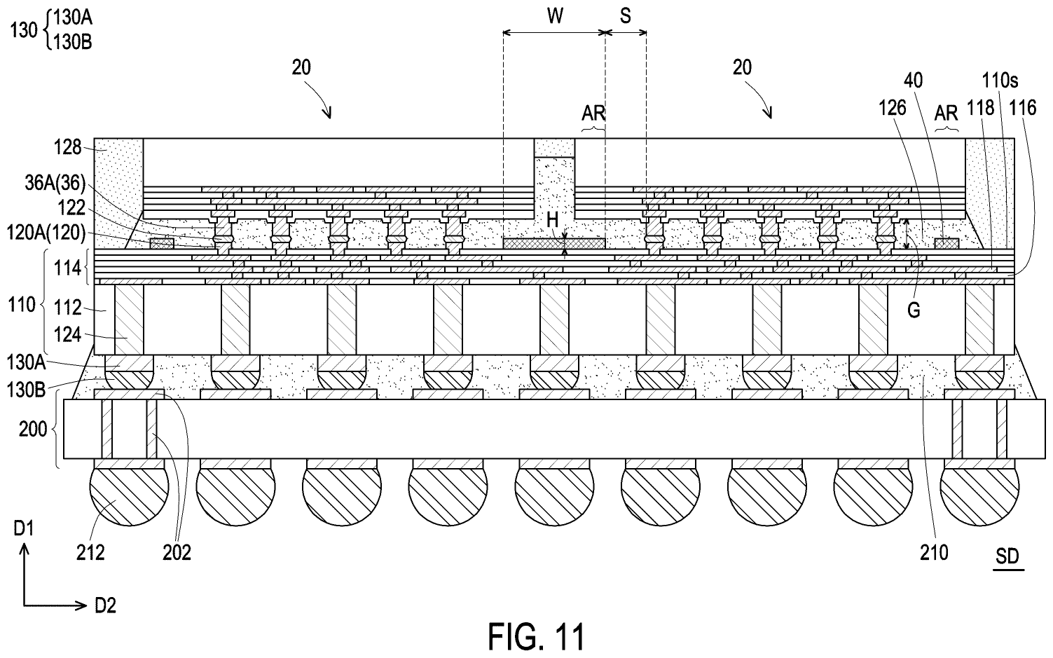

In the above embodiments, the adhesion promotion pattern 40 is separated from the conductive connector 36. However, as shown in FIG. 8, the adhesion promotion pattern 40 of at least one of the integrated circuits 20 may be in direct contact with the conductive connector 36 (e.g., a sidewall of the conductive connector 36). In some embodiments, the adhesion promotion pattern 40 is in direct contact with a portion of the passivation layer 34 surrounding the conductive connector 36. For example, the adhesion promotion pattern 40 is overlying or conformal to (not shown) the portion of the passivation layer 34 surrounding the conductive connector 36. In some embodiments, as shown in FIG. 9, at least one of the adhesion promotion patterns 40 may be in direct contact with the conductive connector 120 (e.g., a sidewall of the conductive connector 120) of the interposer 110. In some embodiments, as shown in FIG. 10A, the adhesion promotion pattern 40 is disposed between and in contact with the adjacent connectors 120. The adhesion promotion pattern 40 between the adjacent connectors 120 may be a part of a closed pattern such as shown in FIG. 10B or a single pattern such as bar-shaped/rectangular pattern (such as the adhesion promotion pattern 40 shown in FIG. 2B). In some embodiments, as shown in FIG. 11, the adhesion promotion pattern 40 is disposed between and separated from the adjacent connectors 120. Similarly, the adhesion promotion pattern 40 between the adjacent connectors 120 may be a part of a closed pattern such as shown in FIG. 10B or a single pattern such as bar-shaped/rectangular pattern (such as the adhesion promotion pattern 40 shown in FIG. 2B).

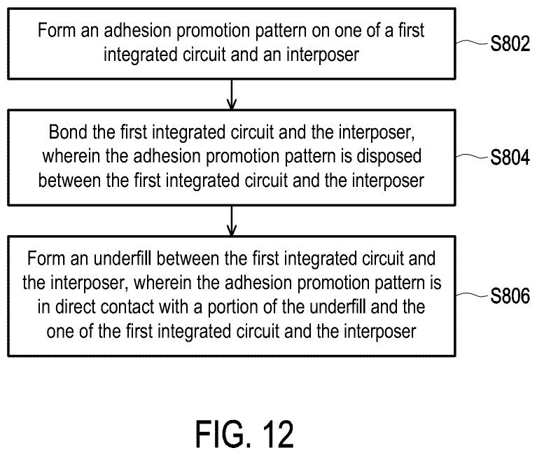

FIG. 12 illustrates a flowchart of a method of forming a semiconductor device according to some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act S802, a first adhesion promotion pattern is formed on one of a first integrated circuit and an interposer. FIG. 1A to FIG. 1D, FIG. 2A to FIG. 2D, FIG. 3B, FIG. 5A, FIG. 6, FIG. 7A and FIG. 8 to FIG. 11 illustrate views corresponding to some embodiments of act S802.

At act S804, the first integrated circuit and the interposer are bonded, wherein the first adhesion promotion pattern is disposed between the first integrated circuit and the interposer. FIG. 3B, FIG. 5A, FIG. 6, FIG. 7A and FIG. 8 to FIG. 11 illustrate views corresponding to some embodiments of act S804.

At act S806, an underfill is formed between the first integrated circuit and the interposer, wherein the adhesion promotion pattern is in direct contact with the underfill and the one of the first integrated circuit and the interposer. FIG. 3C to FIG. 3E, FIG. 5B to FIG. 5D, FIG. 6, FIG. 7B, FIG. 7C and FIG. 8 to FIG. 11 illustrate views corresponding to some embodiments of act S806.

In accordance with some embodiments of the disclosure, a semiconductor device includes a substrate, a passivation layer, a conductive pad, a conductive connector and an adhesion promotion pattern. The passivation layer is disposed on the substrate. The conductive pad is disposed in the passivation layer. The conductive connector is disposed on and electrically connected to the conductive pad. The adhesion promotion pattern is protruded from a surface of the passivation layer, wherein the adhesion promotion pattern is electrically isolated from the conductive connector.

In accordance with some embodiments of the disclosure, a semiconductor device includes an interposer, a first integrated circuit, an underfill and an adhesion promotion pattern. The first integrated circuit is bonded to the interposer. The underfill is disposed between the interposer and the first integrated circuit. The adhesion promotion pattern is protruded from a surface of one of the first integrated circuit and the interposer and disposed between the first integrated circuit and the interposer, and the adhesion promotion pattern is in direct contact with the underfill and one of the first integrated circuit and the interposer.

In accordance with some embodiments of the disclosure, a method of forming a semiconductor device includes the following steps. An adhesion promotion pattern is formed on one of a first integrated circuit and an interposer. The first integrated circuit and the interposer are bonded, wherein the adhesion promotion pattern is disposed between the first integrated circuit and the interposer. An underfill is formed between the first integrated circuit and the interposer, wherein the adhesion promotion pattern is in direct contact with a portion of the underfill and the one of the first integrated circuit and the interposer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a passivation layer on the substrate;
a conductive pad in the passivation layer;
a conductive connector disposed on and electrically connected to the conductive pad; and
an adhesion promotion pattern protruded from a surface of the passivation layer, wherein the adhesion promotion pattern is electrically isolated from the conductive connector.

2. The semiconductor device according to claim 1, wherein a first surface of the adhesion promotion pattern is higher than a first surface of the conductive pad, and a second surface opposite to the first surface of the adhesion promotion pattern is lower than a first surface of the conductive pad.

3. The semiconductor device according to claim 1, wherein the adhesion promotion pattern comprises polyimide, polybenzoxazole (PBO), benzocyclobutene (BCB) or a combination thereof.

4. The semiconductor device according to claim 1, wherein the adhesion promotion pattern is disposed between the conductive connector and a periphery of the passivation layer.

5. The semiconductor device according to claim 1, wherein the adhesion promotion pattern is in direct contact with the passivation layer.

6. The semiconductor device according to claim 1, wherein the adhesion promotion pattern is disposed in a corner area of the semiconductor device.

7. The semiconductor device according to claim 1, wherein the promotion pattern comprises a plurality of adhesion promotion patterns and the conductive connector comprises a plurality of conductive connectors surrounded by the adhesion promotion patterns.

8. A semiconductor device, comprising:
an interposer;
a first integrated circuit bonded to the interposer;
an underfill between the interposer and the first integrated circuit; and
an adhesion promotion pattern protruded from a surface of one of the first integrated circuit and the interposer, wherein the adhesion promotion pattern is disposed between the first integrated circuit and the interposer, and the adhesion promotion pattern is in direct contact with the underfill and the one of the first integrated circuit and the interposer.

9. The semiconductor device according to claim 8, wherein the adhesion promotion pattern is disposed in a periphery area of the first integrated circuit.

10. The semiconductor device according to claim 8, wherein the adhesion promotion pattern is disposed in a corner area of the first integrated circuit.

11. The semiconductor device according to claim 8, wherein the first integrated circuit comprises a first conductive connector, the interposer comprises a second conductive connector, and the underfill surrounds the first conductive connector and the second conductive connector.

12. The semiconductor device according to claim 8, wherein the first integrated circuit comprises a first conductive connector bonded to a second integrated circuit, the first conductive connector is disposed in a passivation layer, and the adhesion promotion pattern is disposed on and in direct contact with the passivation layer.

13. The semiconductor device according to claim 12, wherein a coefficient of thermal expansion of the adhesion promotion pattern is larger than a coefficient of thermal expansion of the passivation layer.

14. The semiconductor device according to claim 8, wherein a second integrated circuit comprises a second conductive connector bonded to the first integrated circuit, the second conductive connector is disposed in a dielectric layer, and the adhesion promotion pattern is disposed on and in direct contact with the dielectric layer.

15. The semiconductor device according to claim 8, wherein the first integrated circuit comprises a plurality of first conductive connectors bonded to a second integrated circuit, the adhesion promotion pattern comprises a plurality of adhesion promotion patterns, and the adhesion promotion patterns are arranged along a periphery of the first integrated circuit to surround the first conductive connectors.

16. The semiconductor device according to claim 8, wherein the adhesion promotion pattern comprises a polymer.

17. A method of forming a semiconductor device, comprising:
forming an adhesion promotion pattern on one of a first integrated circuit and an interposer;
bonding the first integrated circuit and the interposer, wherein the adhesion promotion pattern is disposed between the first integrated circuit and the interposer; and
forming an underfill between the first integrated circuit and the interposer, wherein the adhesion promotion pattern is in direct contact with a portion of the underfill and the one of the first integrated circuit and the interposer.

18. The method according to claim 17, wherein the adhesion promotion pattern is formed on an outermost layer of one of the first integrated circuit and the interposer.

19. The method according to claim 17, wherein the adhesion promotion pattern is formed in a periphery area of the one of the first integrated circuit and the interposer.

20. The method according to claim 17, further comprising performing a thermal process, wherein during the thermal process, the adhesion promotion pattern is expanded to physically connect to the portion of the underfill.
